(19) United States
(12) Patent Application Publication
(10) Pub. No.: US 2026/0247545 A1
(43) Pub. Date: Aug. 20, 2026

(54) ELECTRONIC DEVICE

(71) Applicant: Astemo, Ltd., Chiyoda-ku, Tokyo (JP)

(72) Inventor: Junichi SHIMANE, Hitachinaka-shi, Ibaraki (JP)

(73) Assignee: Astemo, Ltd., Chiyoda-ku, Tokyo (JP)

(21) Appl. No.: 19/164,181

(22) PCT Filed: Jun. 8, 2023
(86) PCT No.: PCT/JP2023/021377

§ 371 Date: Sep. 10, 2025

(51) Int. Cl. H05K 5/00

(52) U.S. Cl. CPC H05K 5/0047

(57) ABSTRACT

An electronic device includes a resin case body having a rectangular opening into which a circuit board is inserted, and a cover that closes the opening of the case body. The case body includes a peripheral wall portion having a rectangular cross section and forming an opening by a pair of first side wall portions facing both surfaces of the circuit board and a pair of second side wall portions connected to the pair of first side wall portions. The peripheral wall portion has a pair of first fitting portions provided in a region of the first side wall portion of the annular end surface on the opening side, and the cover has a pair of second fitting portions fitted to the pair of first fitting portions of the case body by press-fitting. The connection portion between the first side wall portion and the second side wall portion in the peripheral wall portion has a concave portion on the inner wall surface side so as to be thinner than the first side wall portion and the second side wall portion.

### TECHNICAL FIELD

The present invention relates to an electronic device, and more particularly to an electronic device that houses a circuit board in a housing.

### BACKGROUND ART

An electronic device in which a circuit board is housed in a housing is mounted on a vehicle such as an automobile. As a housing of an electronic device, for example, there is a housing including a resin case body that houses a circuit board and a cover that covers an opening of the case body. The resin case body is manufactured by resin molding using a mold. At this time, the opening of the case body may be warped due to a factor such as residual stress, and the height and width of the opening may become uneven.

As a countermeasure against such a problem, for example, a technique described in PTL 1 has been proposed. In the electronic device described in PTL 1, the cover is held in a state of being fixed to the case by engagement between the case-side lock portion provided on the case and the cover-side lock portion provided on the cover side. That is, a snap-fit structure is adopted as a method of fixing a cover to a resin case. Further, when the cover-side lock portion is engaged with the case-side lock portion, the case is pressed from the outside toward the inside of the case opening by the outer claw portion of the cover that faces the outer surface of the case close to the case, whereby the expansion of the case opening (dimensional variation in which the height and width of the opening become non-uniform) is corrected.

### CITATION LIST

### Patent Literature

PTL 1: JP 2021-93446 A

### SUMMARY OF INVENTION

### Technical Problem

However, even if the cover-side lock portion can be engaged with the case-side lock portion by pressing the case with the outer claw portion of the cover to correct the warpage of the case opening as in the technique described in PTL 1, there is a concern that a gap caused by the warpage of the case opening remains between the case and the cover. In a vehicle-mounted electronic device, the gap may become an immersion path into the case. Therefore, there is a demand for minimizing warpage of the case opening that occurs at the time of resin molding using a mold.

In addition, when a snap-fit structure is adopted as a method of fixing a cover to a resin case as in the technique described in PTL 1, the external dimension of the housing tends to increase by the amount of the snap-fit structure.

The present invention has been made to solve the above problems, and an object of the present invention is to provide an electronic device capable of suppressing deformation of a case opening that occurs during resin molding using a mold and avoiding an increase in size of a housing.

### Solution to Problem

The present application includes a plurality of means for solving the above problem. An example of an electronic device includes a circuit board that constitutes an electronic circuit, and a housing that houses the circuit board inside, in which the housing includes a resin case body that has a housing space for housing the circuit board so as to cover both surface sides of the circuit board, and has a rectangular opening for inserting the circuit board into the housing space, and a cover that closes the opening of the case body, the case body includes a peripheral wall portion having a rectangular cross section and forming the opening by four wall portions of a pair of first side wall portions at positions facing both surfaces of the circuit board and a pair of second side wall portions connected to one-side end portions and other-side end portions of the pair of first side wall portions, the peripheral wall portion of the case body includes a pair of first fitting portions provided in regions of the pair of first side wall portions in an annular end surface on the opening side, and extending along an extending direction of the annular end surface, the cover includes a pair of second fitting portions that are respectively fitted to the pair of first fitting portions of the case body by press-fitting, and a connection portion between the first side wall portion and the second side wall portion in the peripheral wall portion of the case body has a concave portion on an inner wall surface side, the concave portion being thinner than the first side wall portion and the second side wall portion.

### Advantageous Effects of Invention

According to an example of the present invention, since the pair of first fitting portions provided in the case body and the pair of second fitting portions provided in the cover form a press-fit fitting structure, the cover can be fixed to the case body without providing a snap-fit structure. Therefore, it is possible to avoid an increase in the outer dimension of the housing while increasing the thickness of the pair of first side wall portions in the opening of the case body and improving the rigidity. Furthermore, since the difference in the contact area between the inner wall surface and the outer wall surface with respect to the molding die at the corner of the peripheral wall portion is reduced by the concave portion of the corner portion (the connection portion between the first side wall portion and the second side wall portion) of the peripheral wall portion of the case body, the residual stress generated at the corner portion is reduced, and the deformation of the opening of the case body can be suppressed. Therefore, it is possible to suppress deformation of the opening of the case body that occurs at the time of resin molding using a mold, and it is possible to avoid an increase in size of the housing.

Problems, configurations, and effects other than those described above will be clarified by the following description of embodiments.

### BRIEF DESCRIPTION OF DRAWINGS

FIG. 1 is a schematic perspective view illustrating an appearance of an electronic device according to a first embodiment of the present invention.

FIG. 2 is a cross-sectional view of the electronic device according to the first embodiment as viewed from the direction of arrows II-II in FIG. 1.

FIG. 3 is a perspective view of the case body of the electronic device according to the first embodiment illustrated in FIG. 1 as viewed from an opening side.

FIG. 4 is a front view illustrating a case body of the electronic device according to the first embodiment illustrated in FIG. 3 as viewed from an opening side.

FIG. 5 is a plan view of a case body of the electronic device according to the first embodiment illustrated in FIG. 3.

FIG. 6 is a perspective view illustrating a cover of the electronic device according to the first embodiment illustrated in FIG. 1.

FIG. 7 is an explanatory view illustrating a method of resin molding of the case body of the electronic device according to the first embodiment.

FIG. 8 is a perspective view of a case body in an electronic device according to a second embodiment of the present invention as viewed from an opening side.

FIG. 9 is a perspective view illustrating a cover of the electronic device according to the second embodiment.

### DESCRIPTION OF EMBODIMENTS

Hereinafter, an embodiment of an electronic device of the present invention will be described with reference to the drawings.

### First Embodiment

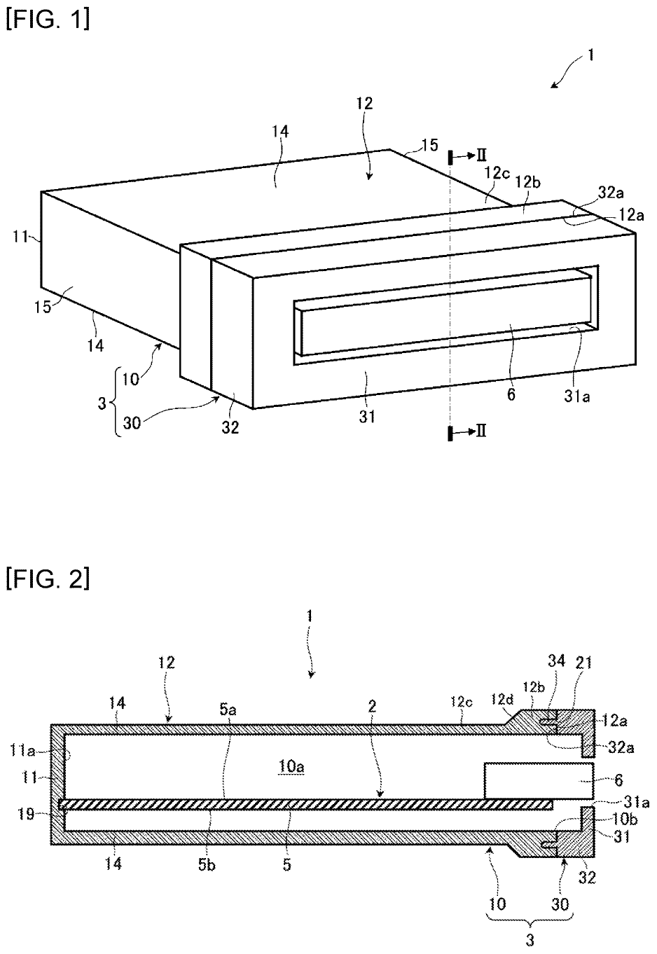

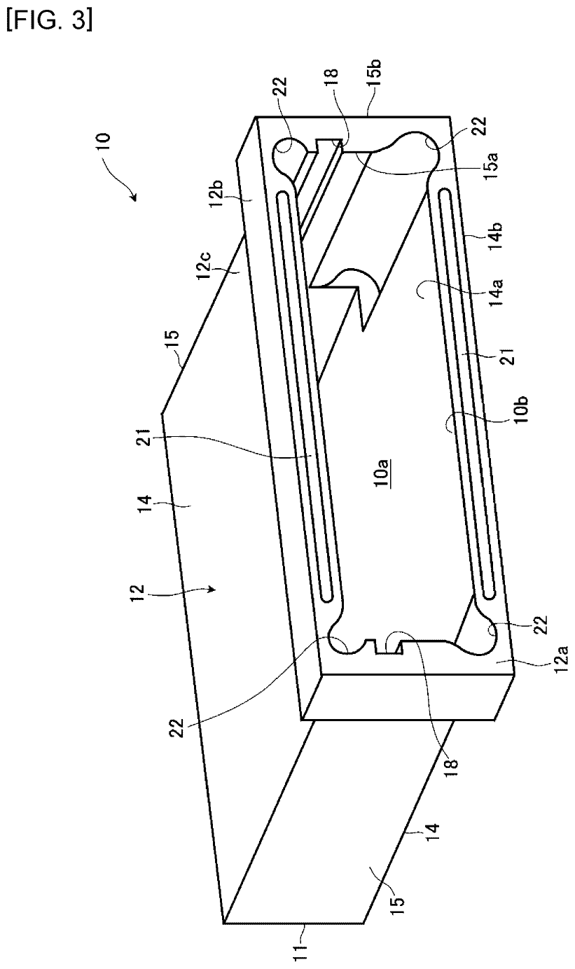

First, a configuration of an electronic device according to a first embodiment will be described with reference to FIGS. 1 and 2. FIG. 1 is a schematic perspective view illustrating an external appearance of the electronic device according to the first embodiment. FIG. 2 is a cross-sectional view of the electronic device according to the first embodiment as viewed from the direction of arrows II-II in FIG. 1.

In FIGS. 1 and 2, an electronic device 1 includes a circuit board 2 (only FIG. 2) constituting an electronic circuit, and a housing 3 that houses the circuit board 2 therein. The electronic device 1 is mounted on a vehicle (not illustrated), for example.

The housing 3 includes a bottomed cylindrical case body 10 having a housing space 10a for housing the circuit board 2 and having a rectangular opening 10b for inserting the circuit board 2 into the housing space 10a on one side, and a cover 30 attached to the case body 10 so as to close the opening 10b of the case body 10. The case body 10 and the cover 30 are resin molded articles. Details of the structures of the case body 10 and the cover 30 of the housing 3 and a molding method thereof will be described later.

As illustrated in FIG. 2, the circuit board 2 includes a wiring board 5 on which wiring is formed, an electronic component (not illustrated) mounted on the wiring board 5, and a connector 6 mounted on the wiring board 5. The wiring board 5 is formed in, for example, a rectangular shape, and has a first surface 5a which is a mounting surface on which the connector 6 is mounted and a second surface 5b which is a back surface of the first surface 5a. The circuit board 2 may be single-sided mounting in which electronic components are mounted on only one of the first surface 5a and the second surface 5b of the wiring board 5, or double-sided mounting in which electronic components are mounted on both surfaces of the first surface 5a and the second surface 5b. The connector 6 enables electrical connection with an external electronic device, and is disposed such that a part thereof is exposed to the outside of the housing 3 through a connector opening 31a described later of the cover 30 of the housing 3.

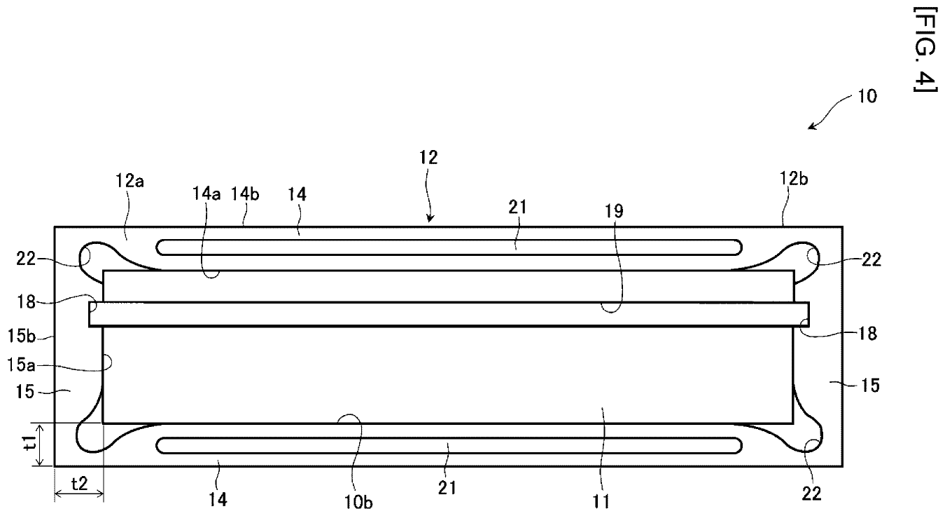

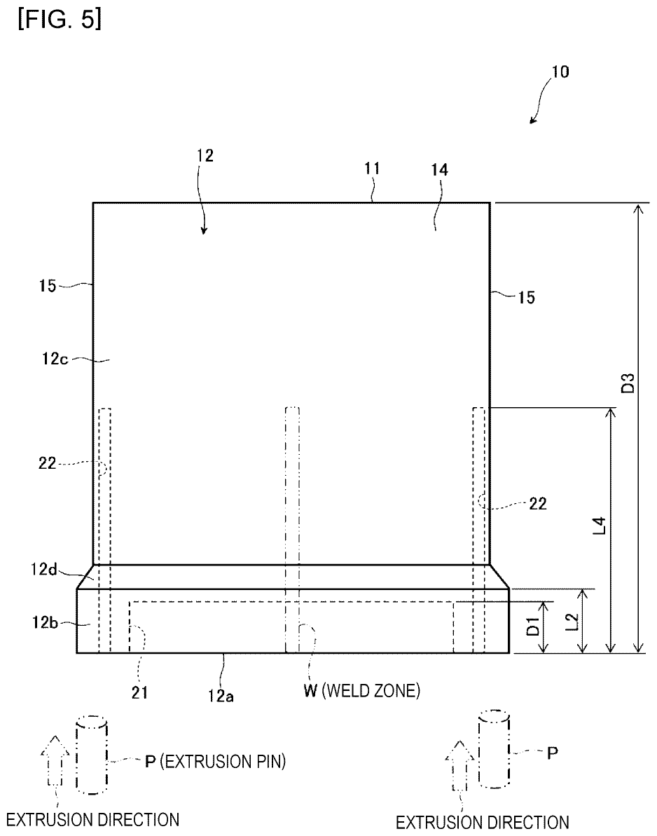

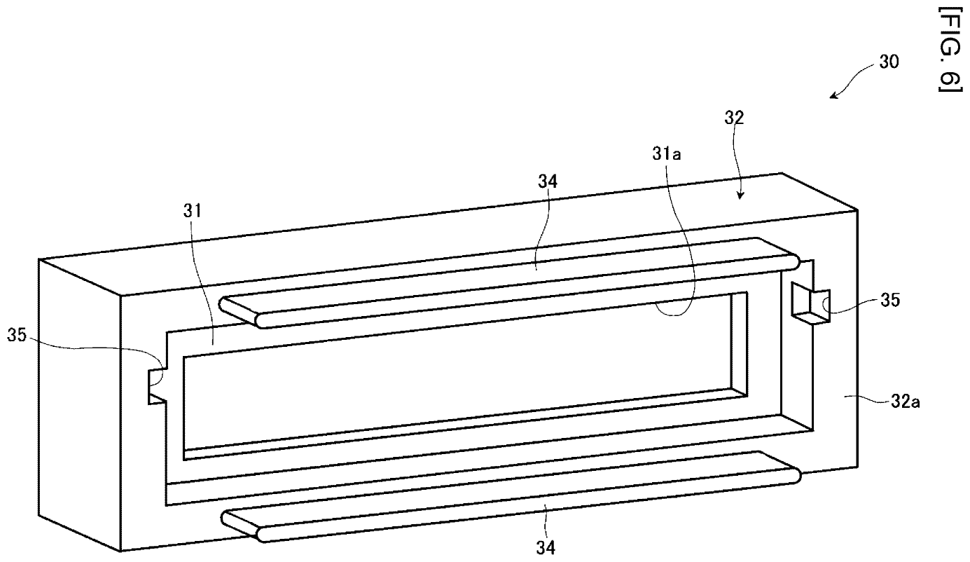

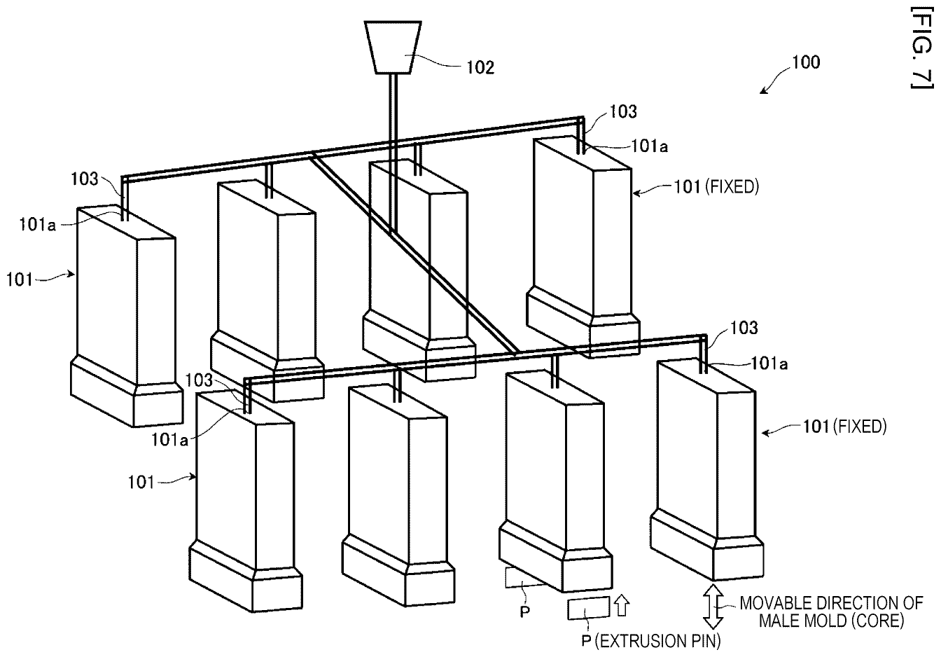

Next, details of a configuration and a structure of a housing of the electronic device according to the first embodiment will be described with reference to FIGS. 1 to 6. FIG. 3 is a perspective view of the case body of the electronic device according to the first embodiment illustrated in FIG. 1 as viewed from the opening side. FIG. 4 is a front view (a view viewed from an opening side) of the case body of the electronic device according to the first embodiment illustrated in FIG. 3. FIG. 5 is a plan view of a case body of the electronic device according to the first embodiment illustrated in FIG. 3. FIG. 6 is a perspective view illustrating a cover of the electronic device according to the first embodiment illustrated in FIG. 1.

As illustrated in FIG. 2, the case body 10 of the housing 3 is configured to cover both surface sides of the first surface 5a and the second surface 5b of the wiring board 5 and to house the circuit board 2 in the housing space 10a so as to surround the outer peripheral edge of the wiring board 5 other than the one side on which the connector 6 is disposed. As illustrated in FIGS. 1 to 3, for example, the case body 10 is formed in a flat substantially rectangular parallelepiped shape, and includes a rectangular bottom wall 11 located on a side opposite to the opening 10b of the case body 10 and a rectangular cylindrical peripheral wall 12 rising from an outer peripheral edge portion of the bottom wall 11.

As illustrated in FIG. 3, the peripheral wall 12 has a distal end portion located on the opposite side to the bottom wall 11 side and forming the opening 10b, and has a rectangular annular end surface 12a on the opening 10b side. As illustrated in FIGS. 2 to 4, the peripheral wall 12 is the peripheral wall 12 is configured by four wall portions, that is, a pair of first side wall portions 14 at positions facing both surfaces of the first surface 5a and the second surface 5b of the circuit board 2 and a pair of second side wall portions 15 connected to one-side end portions and the other-side end portions of the pair of first side wall portions 14, and is formed such that the cross section has a rectangular shape.

As illustrated in FIGS. 3 and 4, a pair of guide grooves 18 extending from the annular end surface 12a of the case body 10 on the opening 10b side to the bottom wall 11 is provided on an inner wall surface 15a of the pair of second side wall portions 15 of the peripheral wall 12. The pair of guide grooves 18 functions as a guide when the circuit board 2 is inserted into the housing space 10a of the case body 10, and has a function of holding a side end portion of the circuit board 2. As illustrated in FIG. 2, an inner wall surface 11a of the bottom wall 11 is provided with a holding groove 19 extending between the pair of second side wall portions 15. The holding groove 19 has a function of holding the other-side end portion (left end portion in FIG. 2) of the circuit board 2.

As illustrated in FIG. 2, the annular end surface 12a on the opening 10b side of the peripheral wall 12 is a portion with which a frame portion 32, which will be described later, of the cover 30 is brought into contact. The annular end surface 12a of the peripheral wall 12 is provided with a fitting structure for fixing the cover 30. Specifically, a pair of first fitting portions 21 is provided in a region of the pair of first side wall portions 14 on the annular end surface 12a of the peripheral wall 12. For example, as illustrated in FIG. 4, the pair of first fitting portions 21 of the peripheral wall 1 is configured as a strip groove extending along the extending direction (left-right direction in FIG. 4) of the annular end surface 12a. A depth D1 (see FIG. 5) of the strip groove serving as a first fitting portion 21 is set so that the cover 30 is reliably fixed to the case body 10 when a second fitting portion (ridge portion) 34 described later of the cover 30 is fitted by press fitting.

For example, as illustrated in FIG. 5, the peripheral wall 12 is configured as a thick portion in which an opening-side peripheral wall portion 12b, which is a portion located on the opening 10b side including the annular end surface 12a, is thicker than the bottom-side peripheral wall portion 12c, which is a portion located on the bottom wall 11 side, by the amount of forming the strip groove as the first fitting portion 21. Accordingly, rigidity of the opening-side peripheral wall portion 12b is improved. A length L2 of the thick portion 12b of the peripheral wall 12 is set to be larger than the depth D1 of the strip groove serving as the first fitting portion 21. The thick portion 12b of the peripheral wall 12 is formed to bulge toward the outer peripheral side of the bottom-side peripheral wall portion 12c and to have a larger thickness. The bottom-side peripheral wall portion 12c is configured to have a thickness that ensures rigidity required when the strip groove is not formed. The peripheral wall 12 has a connecting peripheral wall portion 12d as a connection portion that connects the bottom-side peripheral wall portion 12c thinner than the thick portion 12b and the opening-side peripheral wall portion 12b as a thick portion. The connecting peripheral wall portion 12d is formed in a tapered shape in which the outer peripheral surface expands so that the thickness increases toward the opening-side peripheral wall portion 12b as a thick portion. The connecting peripheral wall portion 12d connects the opening-side peripheral wall portion 12b and the bottom-side peripheral wall portion 12c so as not to generate a step. The inner wall surfaces of the peripheral wall 12 (the inner wall surfaces of the opening-side peripheral wall portion 12b, the bottom-side peripheral wall portion 12c, and the connecting peripheral wall portion 12d) are configured to coincide in position unlike the outer wall surface of the peripheral wall 12.

As illustrated in FIGS. 3 and 4, the portion of the peripheral wall 12 on the opening 10b side including the annular end surface 12a has, on the inner wall surface side, a concave portion 22 in which each corner portion, which is a connection portion between the first side wall portion 14 and the second side wall portion 15, is thinner than the first side wall portion 14 and the second side wall portion 15. In other words, in the portion of the peripheral wall 12 on the opening 10b side, the inner wall surface at each corner portion, which is the connection portion between the first side wall portion 14 and the second side wall portion, is formed as a concave wall surface that becomes the concave portion 22 with respect to an inner wall surface 14a of the first side wall portion 14 and an inner wall surface 15a of the second side wall portion 15 so as to approach an outer wall surface 14b of the first side wall portion 14 and an outer wall surface 15b of the second side wall portion 15 to be smaller in thickness than the thickness t1 of the first side wall portion 14 and the thickness t2 of the second side wall portion 15, respectively, than the inner wall surface 14a of the first side wall portion 14 and the inner wall surface 15a of the second side wall portion 15.

The concave portion 22 on the inner wall surface of each corner portion is formed to include an arc-shaped concave curved surface. The arc-shaped concave curved surface can avoid occurrence of stress concentration. Note that the concave portion 22 can also constitute a concave wall surface by a polygonal surface. The concave portion 22 on the inner wall surface of each corner portion extends from the position of the annular end surface 12a to a position of a length L4 which is ½ or more of the depth length D3, of a depth length D3 from one end (annular end surface 12a) on the opening 10b side of the case body 10 to the other end (outer wall surface of the bottom wall 11). Although described in detail later, the case body 10 is formed with a weld zone W which is a portion where distal end portions of resin flowing when the resin is molded using a mold merge with each other. As illustrated in FIG. 5, there is a concern that the weld zone W may be formed from the annular end surface 12a to a length of ½ of the depth length D3 of the case body 10. The weld zone W is a portion where the strength tends to decrease, and it is necessary to suppress deformation of the weld zone W. Therefore, the concave portion 22 is configured to extend to a portion where generation of the weld zone W is concerned.

As illustrated in FIGS. 1 and 2, for example, the cover 30 of the housing 3 includes a rectangular cover body 31 for closing the opening 10b of the case body 10, and a rectangular frame portion 32 provided at an outer peripheral edge portion of the cover body 31. The cover body 31 is provided with a connector opening 31a for exposing a part of the connector 6 to the outside of the housing 3.

As illustrated in FIG. 2, the frame portion 32 is a portion for fixing the cover 30 to the case body 10, and has a contact surface 32a which is brought into contact with an annular end portion 12a of the case body 10. In a portion of the contact surface 32a of the frame portion 32 that is in contact with the region of the pair of first side wall portions 14 of the annular end surface 12a of the case body 10, a pair of second fitting portions 34 that is fitted to the pair of first fitting portions 21 of the case body 10 by press-fitting is provided. As illustrated in FIGS. 2 and 6, for example, the second fitting portion 34 of the cover 30 is configured as a ridge portion press-fitted into a strip groove 21 of the case body 10. The ridge portion as the second fitting portion 34 of the cover 30 extends along the extending direction of the frame portion 32.

The dimensional relationship between the ridge portion as the second fitting portion 34 of the cover 30 and the strip groove as the first fitting portion 21 of the case body 10 is set to, for example, a range of light press-fitting. Specifically, examples of the range of light press-fitting include a combination of H6 on the strip groove 21 side and js5, jk5, m5, n5, and n6 on the ridge portion 34 side, or a combination of H7 on the strip groove 21 side and k6, m6, n6, and p6 on the ridge portion 34 side in JISB0401-2 (1998).

In the frame portion 32, a pair of notches 35 connected to the guide groove 18 of the case body 10 is provided in a portion of the contact surface 32a abutting on the region of the pair of second side wall portions 15 of the annular end surface 12a of the case body 10. The pair of notches 35 is configured to hold a corner of one side end edge of the circuit board 2 where the connector 6 is located. By sandwiching the circuit board 2 between the holding groove 19 of the bottom wall 11 of the case body 10 and the pair of notches 35 of the frame portion 32 of the cover 30, the circuit board 2 is positioned and held in the housing space 10a of the case body 10.

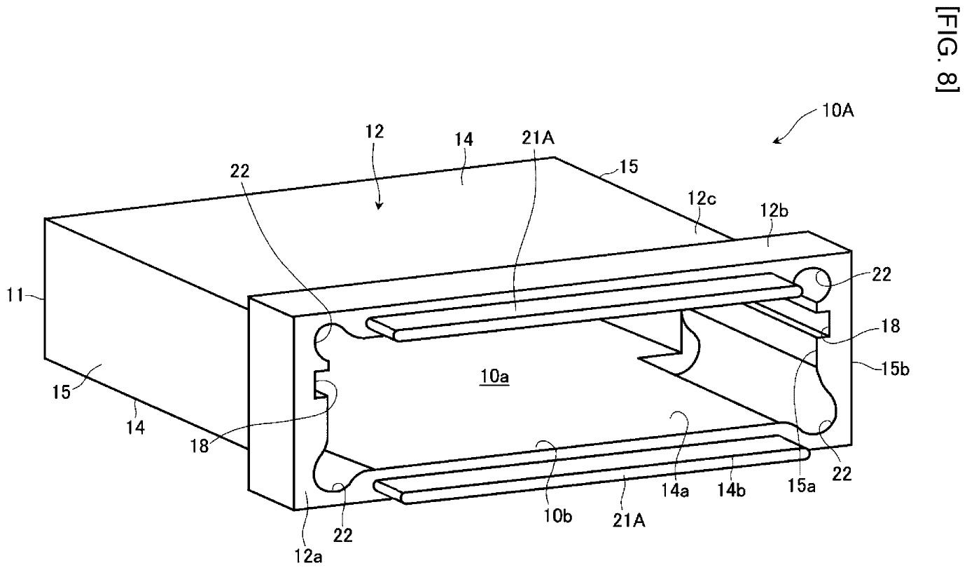

Next, a method for molding the case body of the electronic device according to the first embodiment will be described with reference to FIG. 7. FIG. 7 is an explanatory view illustrating a method of resin molding of the case body of the electronic device according to the first embodiment.

The case body 10 of the electronic device 1 illustrated in FIG. 3 is formed by resin molding using a mold in which a female mold (cavity) 101 as illustrated in FIG. 7 and a male mold (core) (not illustrated) are assembled. A molding system 100 of the case body 10 according to the present embodiment illustrated in FIG. 7 illustrates a multi-piece system having a large number of female molds (cavities) 101 and corresponding male molds (cores). In the molding system 100, a nozzle 102 for injecting molten resin is connected to a large number of female molds (cavities) 101 via a runner 103. Since the yield of the molding system 100 capable of multi-piece molding is improved, production at low cost can be performed. The cover 30 can also be molded with resin by a similar molding system.

The female mold (cavity) 101 is disposed such that a portion corresponding to the bottom wall 11 of the case body 10 faces upward and a portion corresponding to the opening 10b of the peripheral wall 12 faces downward. In the female mold (cavity) 101, a gate 101a is formed in a portion corresponding to the bottom wall 11 of the case body 10. The molten resin flowing into the female mold (cavity) 101 through the gate 101a flows from a portion corresponding to the bottom wall 11 of the case body 10 toward a portion corresponding to the annular end surface 12a. Therefore, as illustrated in FIG. 5, the weld zone W is easily formed at the central portion of the peripheral wall 12 of the case body 10 on the opening side of the pair of first side wall portions 14. There is a concern that the weld zone W formed in this manner is formed from the annular end surface 12a to a length of ½ of the depth length D3 of the case body 10.

In addition, in the molding system 100 illustrated in FIG. 7, a male mold (core) (not illustrated) moves downward to perform mold opening. The case body 10 can be released from the male mold (core) by being extruded upward using, for example, a cylindrical extrusion pin P as illustrated in FIG. 5. For example, the extrusion pin P is disposed at a position where a corner portion of the annular end surface 12a of the peripheral wall 12 is pushed out. Further, as illustrated in FIG. 7, it is also possible to use a plate-shaped square pin P instead of the cylindrical extrusion pin P. In the case of this configuration, the regions of the pair of first side wall portions 14 or the second side wall portions 15 on the annular end surface 12a of the peripheral wall 12 are disposed so as to be pushed out.

In the present embodiment, as illustrated in FIGS. 3 and 4, the concave portion 22 is provided on the inner wall surface side such that each corner portion of the peripheral wall 12 of the case body 10 on the opening 10b side is thinner than the first side wall portion 14 and the second side wall portion 15. As a result, the difference between the contact area of the outer wall surface with respect to the female mold (cavity) 101 and the contact area of the inner wall surface with respect to the male die (core) at the corner portion of the portion of the peripheral wall 12 on the opening 10b side is reduced as compared with the case where the concave portion 22 is not provided, so that the residual stress generated at the corner portion at the time of resin molding using the mold of the case body 10 is reduced. As a result, warpage of the opening of the case body 10 can be suppressed.

Further, in the present embodiment, as illustrated in FIGS. 3 and 4, a strip groove which is the first fitting portion 21 is provided, as a press-fit fitting structure for fixing the cover 30 to the case body 10, in a region of the pair of first side wall portions 14 in the annular end surface 12a of the case body 10. Therefore, since the cover 30 can be fixed to the case body 10 without providing the snap-fit structure, a slide-type mold required for molding the snap-fit structure is unnecessary, and the molding system 100 of the case body 10 can be simplified.

As described above, the electronic device 1 according to the first embodiment includes the circuit board 2 constituting an electronic circuit and the housing 3 for accommodating the circuit board 2 therein. The housing 3 includes the resin case body 10 having the housing space 10a for housing the circuit board 2 so as to cover both sides of the surfaces 5a and 5b of the circuit board 2 and having the rectangular opening 10b for inserting the circuit board 2 into the housing space 10a, and a cover 30 for closing the opening 10b of the case body 10. The case body 10 includes a peripheral wall portion (a portion of the peripheral wall 12 on the opening 10b side) having a rectangular cross section and forming the opening 10b by four wall portions of the pair of first side wall portions 14 at positions facing the both surfaces 5a and 5b of the circuit board 2 and the pair of second side wall portions 15 connected to one-side end portions and the other-side end portions of the pair of first side wall portions 14. The peripheral wall portion of the case body 10 includes the pair of first fitting portions 21 provided in the regions of the pair of first side wall portions 14 of the annular end surface 12a on the opening 10b side and extending along the extending direction of the annular end surface 12a. The cover 30 has the pair of second fitting portions 34 that are fitted to the pair of first fitting portions 21 of the case body 10 by press fitting. The connection portion between the first side wall portion 14 and the second side wall portion 15 in the peripheral wall portion of the case body 10 has the concave portion 22 on the inner wall surface side so as to be thinner than the first side wall portion 14 and the second side wall portion 15.

According to this configuration, since the pair of first fitting portions 21 provided in the case body 10 and the pair of second fitting portions 34 provided in the cover 30 form a press-fit fitting structure, the cover 30 can be fixed to the case body 10 without providing a snap-fit structure. Therefore, it is possible to avoid an increase in the outer dimension of the housing 3 while increasing the thickness of the pair of first side wall portions 14 in the opening of the case body 10 and improving the rigidity. Furthermore, since the difference in the contact area between the inner wall surface and the outer wall surface with respect to the molding die at the corner of the peripheral wall portion is reduced by the concave portion 22 of the corner portion (the connection portion between the first side wall portion 14 and the second side wall portion 15) of the peripheral wall portion (the portion of the peripheral wall 12 on the opening 10b side) of the case body 10, the residual stress generated at the corner portion is reduced, and the deformation of the opening of the case body 10 can be suppressed. Therefore, it is possible to suppress deformation of the opening of the case body 10 that occurs at the time of resin molding using a mold, and it is possible to avoid an increase in size of the housing 3.

Furthermore, since deformation of the opening of the case body 10 is suppressed, generation of a gap between the case body 10 and the cover 30 serving as an immersion path into the case body 10 is suppressed. In addition, by setting the fitting structure by press fitting of the case body 10 and the cover 30 to a tolerance range of light press fitting, it is possible to secure a sealing structure of the housing 3. Therefore, water resistance can be maintained only by a press-fitting structure of the first fitting portion 21 of the case body 10 and the second fitting portion 34 of the cover 30.

In the case body 10 according to the present embodiment, the concave portion 22 at the connection portion (corner portion) between the first side wall portion 14 and the second side wall portion 15 of the peripheral wall portion (the portion of the peripheral wall 12 on the opening 10b side) is formed to include an arc-shaped concave curved surface.

According to this configuration, it is possible to avoid occurrence of stress concentration on the inner wall surface side of each corner portion of the peripheral wall portion.

Further, in the present embodiment, the concave portion 22 extends from the position of the annular end surface 12a to a position of the length L4 or more which is ½ of the depth length D3 in the depth length D3 from one end to the other end of the case body 10 on the opening 10b side.

According to this configuration, when the gate of the mold is provided at the position corresponding to the opposite side of the opening 10b of the case body 10 in order to shorten the molding time of the case body 10, even in a case where the weld zone W is formed in the depth direction from the annular end surface 12a side of the case body 10, it is possible to suppress the deformation due to the decrease in rigidity of the case body 10 by extending the concave portion 22 to the position corresponding to the length in which the generation of the weld zone W in which the stress concentration is likely to occur is assumed.

Further, in the present embodiment, the pair of first fitting portions 21 of the case body 10 is a strip groove extending along the extending direction of the annular end surface 12a, and the pair of second fitting portions 34 of the cover 30 is a ridge portion press-fitted into the strip groove 21 of the case body 10.

According to this configuration, since the fitting structure for fixing the case body 10 and the cover 30 is simplified press-fitting structure, the metal molds for resin molding of the case body 10 and the cover 30 can be simplified.

In the peripheral wall portion (the portion of the peripheral wall 12 on the opening 10b side) of the case body 10 according to the present embodiment, a portion (opening-side peripheral wall portion 12b) from the annular end surface 12a to the position of the depth D1 of the strip groove which is at least the first fitting portion 21 is formed as a thick portion which bulges toward the outer peripheral side and has a larger thickness than the other portion (bottom-side peripheral wall portion 12c) of the case body 10.

According to this configuration, the portion of the case body 10 on the opening 10b side is formed as the thick portion 12b to improve rigidity, so that it is possible to suppress deformation due to a load applied when the case body 10 is released and when the cover is assembled.

In addition, the case body 10 according to the present embodiment has the connecting peripheral wall portion 12d as a connection portion that connects a thin portion (bottom-side peripheral wall portion 12c) having a smaller thickness than the opening-side peripheral wall portion 12b which is a thick portion and the opening-side peripheral wall portion 12b (thick portion). The connecting peripheral wall portion 12d (connection portion) is formed in a tapered shape in which the outer peripheral surface expands so that the thickness increases toward the opening-side peripheral wall portion 12b which is a thick portion.

According to this configuration, by forming the connecting peripheral wall portion 12d in a tapered shape in which the outer peripheral surface expands, the opening-side peripheral wall portion 12b as a thick portion and the bottom-side peripheral wall portion 12c as a relatively thin portion can be connected without generating a step. Therefore, it is possible to avoid stress concentration generated in the connecting peripheral wall portion 12d.

### Second Embodiment

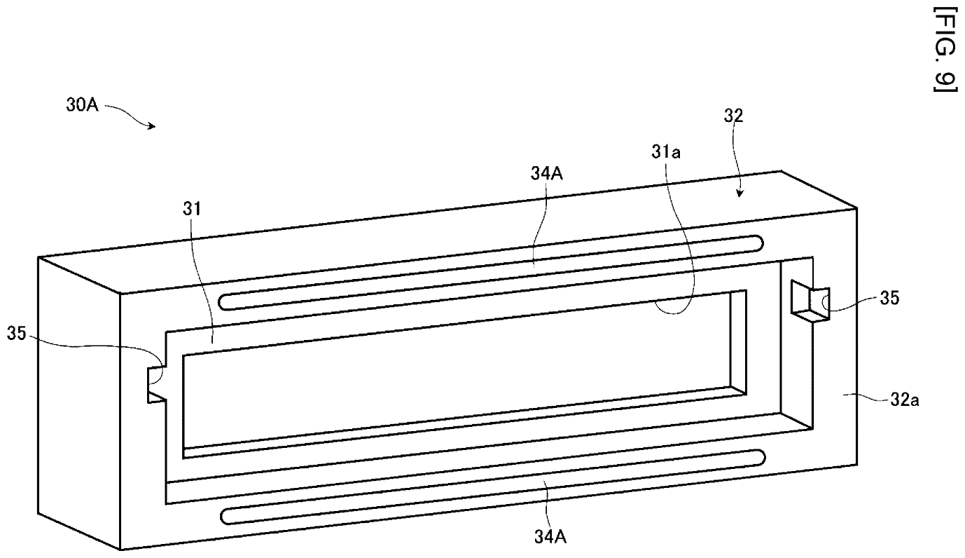

Next, an electronic device according to a second embodiment of the present invention will be described with reference to FIGS. 8 and 9. FIG. 8 is a perspective view of a case body in an electronic device according to the second embodiment of the present invention as viewed from an opening side. FIG. 9 is a perspective view illustrating a cover of the electronic device according to the second embodiment. In FIGS. 8 and 9, components having the same reference numerals as those illustrated in FIGS. 1 to 7 are similar parts, and thus detailed description thereof will be omitted.

The electronic device according to the second embodiment illustrated in FIGS. 8 and 9 is different from the first embodiment in that the fitting structure by press-fitting of a case body 10A and a cover 30A of the housing has an opposite relationship. Other configurations and structures of the electronic device according to the second embodiment are similar to those of the electronic device 1 according to the first embodiment, and description thereof will be omitted.

Specifically, as illustrated in FIG. 8, the annular end surface 12a of the peripheral wall 12 of the case body 10A is provided with a ridge portion as a pair of first fitting portions 21A in a region of the pair of first side wall portions 14. The ridge portion as the first fitting portion 21A protrudes from the annular end surface 12a toward the cover 30A side and extends along the extending direction (left-right direction in FIG. 8) of the annular end surface 12a.

In the cover 30A, as illustrated in FIG. 9, in a portion being in contact with the region of the pair of first side wall portions 14 in the annular end surface 12a of the case body 10 in the contact surface 32a of the frame portion 32, a strip groove into which the ridge portion as the pair of first fitting portions 21 of the case body 10 is provided as a pair of second fitting portions 34A. The strip groove serving as the second fitting portion 34A of the cover 30 extends along the extending direction of the frame portion 32.

In the present embodiment, the ridge portion 21A provided on the annular end surface 12a of the case body 10A and the strip groove 34A provided on the contact surface 32a of the cover 30A constitute a press-fit structure for fixing the cover 30A to the case body 10A. Therefore, since the cover 30A can be fixed to the case body 10A without providing the snap-fit structure, a slide-type mold required for molding the snap-fit structure is unnecessary, and the molding system 100 of the case body 10A can be simplified.

According to the electronic device according to the second embodiment described above, similarly to the first embodiment, since the pair of first fitting portions 21A provided in the case body 10A and the pair of second fitting portions 34A provided in the cover 30A form a press-fit fitting structure, the cover 30A can be fixed to the case body 10A without providing a snap-fit structure. Therefore, it is possible to avoid an increase in the outer dimension of the housing 3 while increasing the thickness of the pair of first side wall portions 14 in the opening of the case body 10A and improving the rigidity. Furthermore, since the difference in the contact area between the inner wall surface and the outer wall surface with respect to the molding die at the corner of the peripheral wall portion is reduced by the concave portion 22 of the corner portion (the connection portion between the first side wall portion 14 and the second side wall portion 15) of the peripheral wall portion (the portion of the peripheral wall 12 on the opening 10b side) of the case body 10A, the residual stress generated at the corner portion is reduced, and the deformation of the opening of the case body 10A can be suppressed. Therefore, it is possible to suppress deformation of the opening of the case body 10A that occurs at the time of resin molding using a mold, and it is possible to avoid an increase in size of the housing 3.

Furthermore, since deformation of the opening of the case body 10A is suppressed, generation of a gap between the case body 10A and the cover 30A serving as an immersion path into the case body 10A is suppressed. In addition, by setting, to a tolerance range of light press fitting, the fitting structure due to press fitting of the case body 10A and the cover 30A, it is possible to secure a sealing structure of the housing 3. Therefore, water resistance can be maintained only by a press-fitting structure of the first fitting portion 21A of the case body 10A and the second fitting portion 34A of the cover 30A.

Further, in the present embodiment, the pair of first fitting portions 21A of the case body 10A is a ridge portion which protrudes from the annular end surface 12a toward the cover 30A side and extends along the extending direction of the annular end surface 12a. The pair of second fitting portions 34A of the cover 30A is a strip groove into which the ridge portion as the pair of first fitting portions 21A of the case body 10A is press-fitted.

According to this configuration, since the fitting structure for fixing the case body 10A and the cover 30A is a simplified press-fitting structure, the metal molds for resin molding of the case body 10A and the cover 30A can be simplified.

### Other Embodiments

Note that the present invention is not limited to the above-described embodiments, and includes various modifications. The above-described embodiments have been described in detail for easy understanding of the present invention, and are not necessarily limited to those having all the described configurations. A part of the configuration of one embodiment can be replaced with the configuration of another embodiment, and the configuration of another embodiment can be added to the configuration of one embodiment. In addition, it is also possible to add, delete, and replace other configurations for a part of the configuration of each embodiment.

For example, in the above-described embodiments, the example of the configuration in which the connector 6 is mounted on the circuit board 2 has been described. However, the electronic device may have a configuration in which the connector is not mounted on the circuit board, for example, when information is transmitted to an external electronic device by communication.

Furthermore, in the above-described embodiments, an example has been described in which the concave portion 22 of the corner portion (the connection portion between the first side wall portion 14 and the second side wall portion 15) of the case bodies 10 and 10A is formed from the annular end surface 12a to the position of the length L4 that is ½ or more of the depth length D3 of the case bodies 10 and 10A. However, the concave portion 22 may extend only over the range of the opening-side peripheral wall portion 12b as the thick portion. However, in this configuration, as compared with the above-described embodiments, the effect of Suppressing the warpage (deformation) of the openings of the case bodies 10 and 10A may be reduced.

Furthermore, in the above-described embodiments, an example has been described in which the cross section of the peripheral walls 12 of the case bodies 10 and 10A is formed in a rectangular shape from the annular end surface 12a to the bottom wall 11. However, as long as the peripheral wall 12 has a rectangular cross section up to the position where the concave portion 22 of the corner portion extends, a configuration in which the cross section of the subsequent portion is not rectangular is also possible.

### Reference Signs List

1 electronic device

2 circuit board

5a first surface

5b second surface

3 housing

10, 10A case body

10a housing space

10b opening

12 peripheral wall

12a annular end surface

12b opening-side peripheral wall portion (thick portion)

12c bottom-side peripheral wall portion (thin portion)

12d connecting peripheral wall portion (connection portion)

14 first side wall portion

15 second side wall portion

21 first fitting portion (strip groove)

21A first fitting portion (ridge portion)

22 concave portion

30, 30A cover

34 second fitting portion (ridge portion)

34A second fitting portion (strip groove)

1. An electronic device comprising:
a circuit board that constitutes an electronic circuit; and
a housing that houses the circuit board inside,
wherein
the housing includes:
a resin case body that has a housing space for housing the circuit board so as to cover both surface sides of the circuit board, and has a rectangular opening for inserting the circuit board into the housing space; and
a cover that closes the opening of the case body,
the case body includes a peripheral wall portion having a rectangular cross section and forming the opening by four wall portions of a pair of first side wall portions at positions facing both surfaces of the circuit board and a pair of second side wall portions connected to one-side end portions and other-side end portions of the pair of first side wall portions,
the peripheral wall portion of the case body includes a pair of first fitting portions provided in regions of the pair of first side wall portions in an annular end surface on the opening side, and extending along an extending direction of the annular end surface,
the cover includes a pair of second fitting portions that are respectively fitted to the pair of first fitting portions of the case body by press-fitting, and
a connection portion between the first side wall portion and the second side wall portion in the peripheral wall portion of the case body has a concave portion on an inner wall surface side, the concave portion being thinner than the first side wall portion and the second side wall portion.

2. The electronic device according to claim 1, wherein
the concave portion at the connection portion of the peripheral wall portion is formed to include an arc-shaped concave curved surface.

3. The electronic device according to claim 1, wherein
the concave portion in the connection portion of the peripheral wall portion extends from a position of the annular end surface to a position of ½ or more of a depth length from one end to another end on the opening side of the case body.

4. The electronic device according to claim 1, wherein
the pair of first fitting portions of the case body is a strip groove extending along an extending direction of the annular end surface, and
the pair of second fitting portions of the cover is a ridge portion press-fitted into the strip groove of the case body.

5. The electronic device according to claim 1, wherein
the pair of first fitting portions of the case body is a ridge portion that protrudes from the annular end surface toward the cover side and extends along an extending direction of the annular end surface, and
the pair of second fitting portions of the cover is a strip groove into which the ridge portion of the case body is press-fitted.

6. The electronic device according to claim 4, wherein
the peripheral wall portion of the case body is formed as a thick portion in which a portion from the annular end surface to at least a position of a depth of the strip groove bulges toward an outer peripheral side more than other portions of the case body so as to have a larger thickness.

7. The electronic device according to claim 6, wherein
the case body includes a connection portion that connects a thin portion having a thickness smaller than a thickness of the thick portion and the thick portion, and
the connection portion is formed in a tapered shape in which an outer peripheral surface expands so that a thickness increases toward the thick portion.
